(19) United States
(12) Patent Application Publication
(10) Pub. No.: US 2005/0145881 A1
(43) Pub. Date: Jul. 7, 2005

(54) Depletion-merged FET design in bulk silicon

(76) Inventors: Shui-Ming Cheng, Chu-pei City (TW); Ka-Hing Fung, Hsin-Chu (TW); Yin-Pin Wang, Kaohsiung City (TW)

Correspondence Address: SLATER & MATSIL, L.L.P., 17950 PRESTON ROAD, SUITE 1000, DALLAS, TX, 75252, US

(21) Appl. No.: 10/749,080

(22) Filed: Dec. 30, 2003

(51) Int. Cl. H01L 31/0328

(52) U.S. Cl. 257/192

(57) ABSTRACT

Field effect transistors having reduced reverse body effects and reduced parasitic junction capacitance and a method of manufacture. The FET's comprise source/drain region pairs formed in said bulk silicon, each pair separated by a channel region. The depletion region associated with each of the source/drain regions of a pair are fully merged by selective ion implantation. A gate electrode is formed or deposited over the channel region of each FET in the normal manner.

### TECHNICAL FIELD

The present invention relates generally to semiconductor devices manufactured in bulk silicon, and more particularly to such semiconductor devices having reduced reverse body effects and reduced parasitic junction capacitance similar to that available with PD-SOI (partially depleted silicon-on-insulator) semiconductors, but without the undesirable “floating body” effects of a PD-SOI transistor.

### BACKGROUND

As will be appreciated by those skilled in the art, PD-SOI transistors are often favored over transistors manufactured in bulk silicon as providing several advantages including reduced junction capacitance and absence of the reverse body effects, etc. The PD-SOI transistor has a silicon body thickness that is thicker than the maximum depletion layer within the transistor such that a portion or region of the body of the PD-SOI transistor is undepleted. Since the undepleted body portions of the PD-SOI transistor is not tied or directly connected to any voltage, it is commonly referred to as being a “floating body” region. The “floating body” region causes undesirable effects in the PD-SOI device because of charges that accumulate in the floating body region, which is formed directly below the channel region. Although PD-SOI transistors are easily manufactured, the undesirable effects of the “floating body” region cause substantial variations in the circuit performance, which in turn presents very serious design challenges to the engineers.

Therefore, it would be advantageous if FET (field effect transistors) having reduced reverse body effects and reduced parasitic junction capacitance could be manufactured without the floating body effects of a PD-SOI transistor.

### SUMMARY OF THE INVENTION

These and other problems are generally solved or circumvented, and technical advantages are generally achieved, by preferred embodiments of the present invention, which discloses a field effect transistor formed on a bulk silicon substrate that has the advantages of reduced reverse body effects and reduced parasitic capacitance of a PD-SOI transistor, but not the disadvantages of the “floating body effects” also associated with PD-SOI transistors. The field effect transistor of this invention comprises a first source/drain region, a second source/drain region, a channel region separating the first and second source/drain regions and a depletion region defined under the channel region and between the first and second source/drain regions, where the depletion regions associated with the first and second source/drain regions have merged because of selected ion implantation of “graded” areas of the source/drain regions. A gate member is formed over the channel region in a normal manner. The field effect transistor shows improved characteristics where the depletion areas have only partially merged. However, the characteristics are most improved when the merged depletion region is a fully merged depletion region.

In a manner well known in the art, the field effect transistors found in the bulk silicon also typically include a pair of shallow oxide trenches for isolating said field effect transistor, (i.e., STI).

Although discussed above with respect to a single transistor, it will be appreciated that a multiplicity of field effect transistors will typically be formed in the bulk silicon substrate.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### DESCRIPTION OF THE DRAWINGS

For a more complete understanding of the present invention, and the advantages thereof, reference is now made to the following descriptions taken in conjunction with the accompany drawing, in which:

FIG. 1 is a prior art illustration of an FET formed in bulk silicon;

FIG. 2A illustrates another prior art illustration of an FET formed in bulk silicon, and FIGS. 2B and 2C illustrate FET's formed in bulk silicon according to the present invention;

FIG. 3 is a graph comprising the “reverse body effects” of the FET structure of FIGS. 2A, 2B and 2C;

FIG. 4 is a graph illustrating the current leakage of an FET with fully merged depletion regions; and

FIG. 5 illustrates improvement in C_{jswg} parasitic capacitance of an FET employing a fully merged depletion region according to the teachings of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

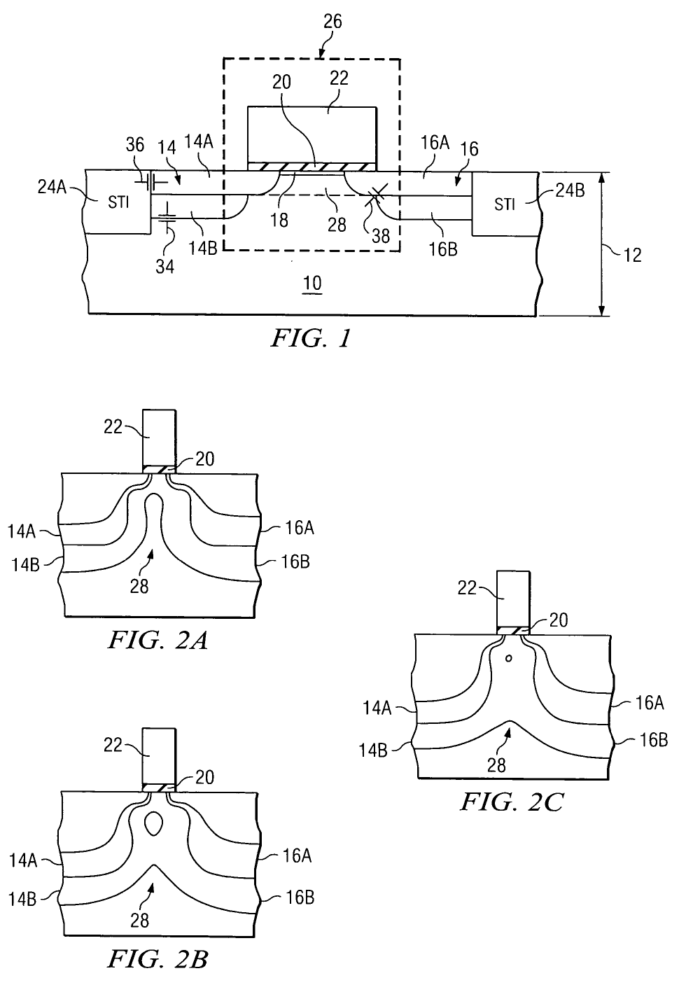

Referring now to FIG. 1, there is illustrated a prior art bulk silicon device. As shown in FIG. 1, there is included a bulk silicon substrate 10. The term “bulk silicon” is used to include a semiconductor device formed in a layer or wafer of silicon having a substantial thickness as indicated by double-headed arrow 12 and to distinguish from a SOI (silicon-on-insulator) structure, which forms semiconductor devices in a thin layer of silicon.

The formation of an FET semiconductor device formed in the bulk silicon will now be described. A first graded source/drain region, such as source region 14 and a second graded source/drain region, such as drain region 16 is formed in the bulk silicon 10 by ion implantation. Extending between the source region 14 and drain region 16 is a channel region 18. As mentioned, the source regions and drain regions 14 and 16, respectively, are “graded” implant regions as indicated by the two areas 14a and 14b and 16a and 16b associated with a pair of source/drain regions as formed by two different ion implantations. A gate oxide 20 is formed over the channel region 18 and a poly silicon gate 22 is formed on top of the gate oxide to complete the field effect transistor. A pair of STI (shallow trench isolation) regions 24a and 24b is also typically included to separate the field effect transistor from other circuits or field effect transistors formed in the bulk silicon 10. Other techniques for isolating devices, such as the formation of field oxide areas, could of course be used. Of particular interest according to the present invention, is the dotted line area 26, which includes an electron depletion region 28 between the source 14 and drain 16 regions and for a short distance below the channel region 18.

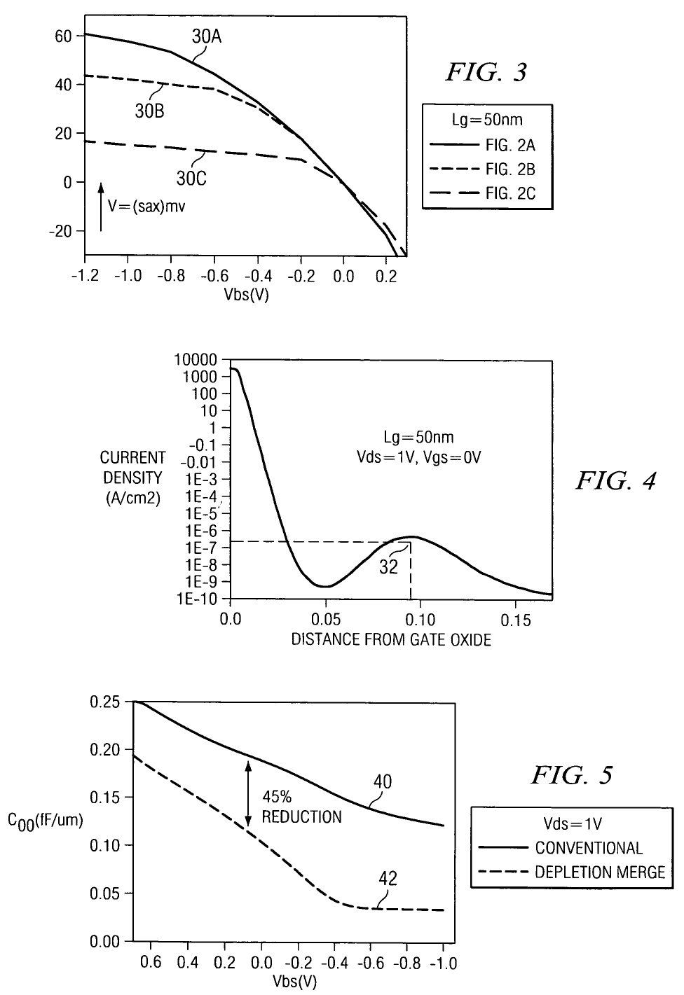

Referring now to FIGS. 2A, 2B and 2C, there is illustrated variations in the area of interest 26 according to the present invention. Those portions of FIGS. 2A, 2B and 2C that are equivalent to the elements of FIG. 1 will carry the same reference number. Therefore, FIG. 2A illustrates that the graded source regions 14a and 14b are very close to the drain regions 16a and 16b but do not touch, and therefore, the depletion area has not merged. FIG. 2B on the other hand, shows a partially merging of the depletion area and FIG. 2C shows the source and drain areas 14 and 16 overlapping, which results in fully merged depletion regions. Thus, it is seen that the merged depletion area is a result of the overlapping of the graded source/drain regions, which in turn is a result of optimizing the location and density of the ion implantation step used to form the graded source and drain regions 14 and 16. It has been determined that an ion implantation density of between about E¹²/cm² to about 5E¹³/cm² is particularly suitable for use with the invention. As was discussed above, advantages of the PD-SOI transistor structure are the reduced parasitic capacitance and the reduced reverse body effects.

Referring now to FIG. 3, there is illustrated the significantly reduced reverse body effects obtained by fully merging the depletion regions according to the teachings of the present invention. As shown in the structure of FIG. 2A, the depletion regions are not merged and the reverse body effects for the structure of FIG. 2A are illustrated by curve 30a. As can be seen, the Vₜ₍ₛₐₜ₎ is about 60 milivolts at a V_{bs} (V_{bs}=voltage bias between the substrate and the source) of 1.2 volts. Curve 30B of FIG. 3B illustrates the reverse body effects for the partially merged depletion region structure of FIG. 2B. As shown at a V_{bs} of −1.2 volts, the Vₜ₍ₛₐₜ₎ has improved to about 44 milivolts, but is still high. However, curve 30c, which illustrates the reverse body effects of the fully merged depletion region structure of FIG. 3C has been significantly reduced to less than 20 milivolts.

In addition, it has been discovered that the merging of the depletion region results in a reduction of the DIBL (drain induced barrier lowering). The sub-threshold swing at high V_{ds} (V_{ds}=high-drain-to source bias) is not significantly degraded (such that the IDBL resulting from the depletion merging may be less than that resulting from short channel effects. Significantly it is seen by referring to FIG. 4 that merging of the depletion regions results in very small current leakage at the merged region. That is, there is no increase in the risk of source/drain punch-through. More specifically, the curve of FIG. 4 illustrates the current density as a function of the distance from the gate oxide. Although there is a slight increase in the amount of leakage in the merged region at a location of about 0.9 micrometers from the gate oxide as indicated by reference number 32, the amount of leakage is still negligible or about 1E⁻⁷ amps/centimeters² as shown.

Referring again to FIG. 1, the parasitic capacitance C_{jb}, C_{jsw}, and C_{jswg} indicated by reference numbers 34, 36 and 38, respectively, are illustrated. Parasitic capacitance and more specifically the high sidewall gate capacitance C_{jswg} 38 degrade the AC performance of the transistor. However, as shown in the graph of FIG. 5, merging the depletion region of the transistor also results in a significant reduction in the C_{jswg} capacitance. As shown, the depletion region according to this invention results in about a 45% reduction. The C_{jswg} capacitance versus the V_{bs} for a prior art transistor is indicated by curve 40 and the depletion-merged transistor of the present invention is illustrated by curve 42. Although the present invention and its advantages have been described in detail, it should be understood that various changes, substitutions and alterations can be made herein without departing from the spirit and scope of the invention as defined by the appended claims.

Moreover, the scope of the present application is not intended to be limited to the particular embodiments of the process, machine, manufacture, composition of matter, means, method and steps described in the specification. As one of ordinary skill in the art will readily appreciate from the disclosure of the present invention, processes, machines, manufacture, compositions of matter, means, methods, or steps, presently existing or later to be developed, that preform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A field effect transistor having reduced reverse body effects and reduced parasitic junction capacitance comprising:
a bulk silicon substrate;
a first source/drain region having a first depletion region associated therewith formed in said bulk silicon substrate;
a second source/drain region having a second depletion region associated therewith formed in said bulk silicon substrate;
a channel region separating said first and second source/drain regions;
a merged depletion region defined in said bulk silicon substrate, and under said channel region and between said first and second source/drain regions by merging said first and second depletion regions; and
a gate member formed over said channel region.

2. The field effect transistor of claim 1 wherein said merged depletion region is a fully merged depletion region.

3. The field effect transistor of claim 1 wherein said merged depletion region has an ion implantation density of between about E¹²/cm² to about 5E¹³/cm².

4. The field effect transistor of claim 1 further comprising a pair of shallow trench isolation (STI) regions for isolating said field effect transistor.

5. The field effect transistor of claim 1 wherein said regions comprise first and second source/drain regions formed by optimally grading said source/drain regions to fully merge said depletion regions.

6. A multiplicity of field effect transistors having reduced reverse body effects and reduced parasitic junction capacitance, each of said multiplicity of field effect transistors comprising:
a bulk silicon substrate
a first source/drain region having a first depletion region associated therewith formed in said bulk silicon substrate;
a second source/drain region having a second depletion region associated therewith formed in said bulk silicon substrate;
a channel region formed in said bulk silicon substrate separating said first and second source/drain regions;
a merged depletion region defined in said bulk silicon substrate under said channel region and between said first and second source/drain regions by merging said first and second depletion regions;
a gate member formed over said channel region; and
a multiplicity of shallow trench isolation (STI) regions separating said multiplicity of field effect transistors from each other.

7. The multiplicity of field effect transistors of claim 6 wherein said merged depletion region has an ion implantation density of between about E¹²/cm² to about 5E¹³/cm².

8. A method of manufacturing field effect transistors having reduced reverse body effects and reduced parasitic capacitance on a bulk silicon substrate comprising the steps of:
providing a bulk silicon substrate;
forming a multiplicity of source/drain region pairs, each separated by a channel region in said bulk silicon and having a depletion region associated therewith;
merging said depletion regions of said source/drain pairs by selective ion implantation; and
depositing a control gate over said channel region.

9. The method of claim 8 wherein said first and second source/drain regions are graded source/drain regions and wherein said step of ion implantation comprises the step of ion implanting said graded first and second source/drain regions in an optimal pattern and with an optimal density to merge said depletion regions.

10. The method of claim 8 wherein said step of merging said depletion region comprises the step of implanting ions at a density of between about E¹²/cm² and about 5E¹³/cm².

11. The method of claim 8 wherein said step of merging comprises the step of fully merging said depletion regions.
